(19) United States
(12) Patent Application Publication
(10) Pub. No.: US 2023/0077383 A1
(43) Pub. Date: Mar. 16, 2023

(54) LIGHT-EMITTING DEVICE AND PROJECTOR

(71) Applicants: SEIKO EPSON CORPORATION, Tokyo (JP); SOPHIA SCHOOL CORPORATION, Tokyo (JP)

(72) Inventors: Shunsuke ISHIZAWA, TOKYO TO SHINJUKU KU (JP); Katsumi KISHINO, TOKYO TO AKIRUNO-SHI (JP)

(73) Assignees: SEIKO EPSON CORPORATION, Tokyo (JP); SOPHIA SCHOOL CORPORATION, Tokyo (JP)

(21) Appl. No.: 17/943,164

(22) Filed: Sep. 12, 2022

(30) Foreign Application Priority Data
Sep. 13, 2021 (JP) 2021-148471

(51) Int. Cl. H01S 5/042; H04N 9/31

(52) U.S. Cl. CPC H01S 5/04253; H04N 9/3161

(57) ABSTRACT

A light-emitting device includes a laminate provided at a substrate, a first electrode provided on an opposite side of the laminate from the substrate, and a second electrode provided on an opposite side of the first electrode from the substrate. The laminate includes a first semiconductor layer of a first conductivity type, a second semiconductor layer of a second conductivity type different from the first conductivity type, and a light-emitting layer provided between the first semiconductor layer and the second semiconductor layer. The first semiconductor layer is provided between the substrate and the light-emitting layer. The first electrode constitutes a plurality of column portions. The second electrode is coupled to the plurality of column portions. The first electrode is a transparent electrode formed of a metal oxide transmitting light generated at the light-emitting layer.

The present application is based on, and claims priority from JP Application Serial Number 2021-148471, filed Sep. 13, 2021, the disclosure of which is hereby incorporated by reference herein in its entirety.

### BACKGROUND

### 1. Technical Field

The present disclosure relates to a light-emitting device and a projector.

### 2. Related Art

Semiconductor lasers are expected as next-generation light sources having high luminance. In particular, semiconductor lasers to which nanocolumns are applied are expected to realize high-power light emission with a narrow radiation angle thanks to the photonic crystal effect of nanocolumns.

For example, WO 2010/023921 describes a semiconductor light-emitting element that includes nanocolumns formed of fine columnar crystals including an n-type clad layer, an active layer, and a p-type semiconductor layer including a p-type clad layer, and a p-side electrode of indium tin oxide (ITO) or the like electrically coupled to the p-type semiconductor layer.

When the distance between the p-side electrode and the active layer is small, the light generated at the active layer leaks to the p-side electrode side, and is easily absorbed at the p-side electrode. Increasing the distance between the p-side electrode and the active layer can reduce the absorption of light at the p-side electrode. However, making the p-type semiconductor layer thicker to increase the distance between the p-side electrode and the active layer will increase the resistance.

### SUMMARY

An aspect of a light-emitting device according to the present disclosure includes: a substrate, a laminate provided at the substrate, a first electrode provided on an opposite side of the laminate from the substrate, and a second electrode provided on an opposite side of the first electrode from the substrate, wherein the laminate includes a first semiconductor layer of a first conductivity type, a second semiconductor layer of a second conductivity type different from the first conductivity type, and a light-emitting layer provided between the first semiconductor layer and the second semiconductor layer, the first semiconductor layer is provided between the substrate and the light-emitting layer, the first electrode constitutes a plurality of column portions, the second electrode is coupled to the plurality of column portions, and the first electrode is a transparent electrode formed of a metal oxide transmitting light generated at the light-emitting layer.

One aspect of a projector according to the present disclosure includes one aspect of the light-emitting device.

### BRIEF DESCRIPTION OF THE DRAWINGS

FIG. 1 is a cross-sectional view schematically illustrating a light-emitting device according to the present embodiment.

FIG. 2 is a cross-sectional view schematically illustrating a manufacturing step for the light-emitting device according to the present embodiment.

FIG. 3 is a cross-sectional view schematically illustrating a light-emitting device according to a first modified example of the present embodiment.

FIG. 4 is a cross-sectional view schematically illustrating a light-emitting device according to a second modified example of the present embodiment.

FIG. 5 is a plan view schematically illustrating a light-emitting device according to a fourth modified example of the present embodiment.

FIG. 6 is a cross-sectional view schematically illustrating the light-emitting device according to the fourth modified example of the present embodiment.

FIG. 7 is a plan view schematically illustrating a light-emitting device according to a fifth modified example of the present embodiment.

FIG. 8 is a cross-sectional view schematically illustrating the light-emitting device according to the fifth modified example of the present embodiment.

FIG. 9 is a view schematically illustrating a projector according to the present embodiment.

### DESCRIPTION OF EXEMPLARY EMBODIMENTS

Hereinafter, preferred embodiments of the present disclosure will be described in detail using the appended drawings. Note that the embodiments described below are not intended to unduly limit the content of the present disclosure as set forth in the claims. Furthermore, not all of the configurations described below necessarily represent essential requirements of the present disclosure.

1. Light-Emitting Device

### 1.1. Overall Configuration

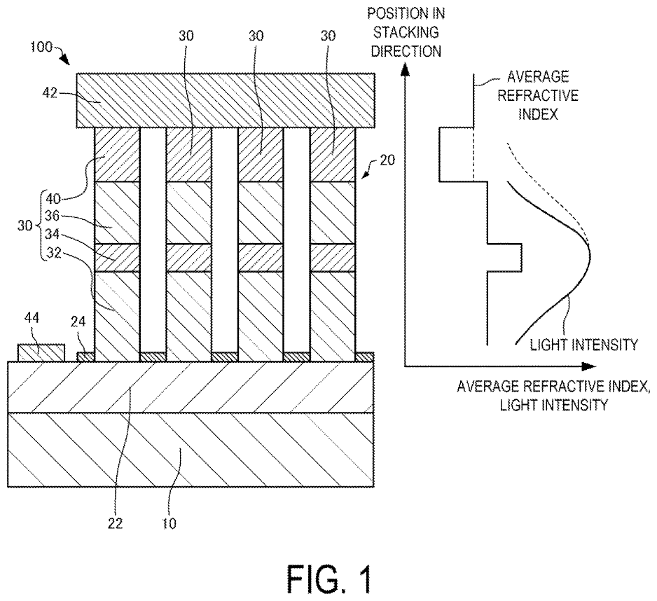

First, a light-emitting device according to the present embodiment will be described with reference to drawings. FIG. 1 is a cross-sectional view schematically illustrating a light-emitting device 100 according to the present embodiment.

As illustrated in FIG. 1, the light-emitting device 100 includes, for example, a substrate 10, a laminate 20, first electrodes 40, a second electrode 42, and a third electrode 44. The light-emitting device 100 is a semiconductor laser, for example.

The substrate 10 is, for example, an Si substrate, a GaN substrate, a sapphire substrate, an SiC substrate, or the like.

The laminate 20 is provided at the substrate 10. In the illustrated example, the laminate 20 is provided on the substrate 10. The laminate 20 includes, for example, a buffer layer 22. Further, the laminate 20 constitutes column portions 30.

In the present specification, when a light-emitting layer 34 is used as reference in the stacking direction of the laminate 20 (hereinafter also simply referred to as the “stacking direction”), the direction going from the light-emitting layer 34 toward a second semiconductor layer 36 is referred to as “upward”, and the direction going from the light-emitting layer 34 toward a first semiconductor layer 32 is referred to as “downward”. Directions orthogonal to the stacking direction are also referred to as “in-plane directions”. Furthermore, the “stacking direction of the laminate 20” refers to the stacking direction of the first semiconductor layer 32 and the light-emitting layer 34 of the column portions 30.

The buffer layer 22 is provided on the substrate 10. The buffer layer 22 is, for example, an n-type GaN layer doped with Si. A mask layer 24 for growing the column portions 30 is provided on the buffer layer 22. The mask layer 24 is, for example, a silicon oxide layer, a titanium layer, a titanium oxide layer, an aluminum oxide layer, or the like.

The column portions 30 are provided on the buffer layer 22. The column portions 30 each have a columnar shape protruding upward from the buffer layer 22. In other words, the column portions 30 protrude upward from the substrate 10 via the buffer layer 22. The column portions 30 are also referred to as, for example, nanocolumns, nanowires, nanorods, and nanopillars. The planar shape of the column portion 30 is, for example, a polygon such as a hexagon, or a circle.

The diameter of the column portion 30 is, for example, not less than 50 nm and not greater than 500 nm. Setting the diameter of the column portion 30 to not greater than 500 nm allows a high-quality crystalline light-emitting layer 34 to be obtained, and the strain inherent in the light-emitting layer 34 to be reduced. This makes it possible to amplify light generated at the light-emitting layer 34 with high efficiency.

Note that when the planar shape of the column portion 30 is a circle, the “diameter of the column portion” is the diameter; and when the planar shape of the column portion 30 is not a circle, it is the diameter of the minimum inclusion circle. For example, when the planar shape of the column portion 30 is a polygon, the diameter of the column portion 30 is the diameter of the smallest circle including the polygon; and when the planar shape of the column portion 30 is an ellipse, it is the diameter of the smallest circle including the ellipse.

The column portions 30 are provided in plurality. The spacing between adjacent column portions 30 is, for example, not less than 1 nm and not greater than 500 nm. The plurality of column portions 30 are arranged in a predetermined pitch in a predetermined direction as viewed from the stacking direction. The plurality of column portions 30 are disposed in a triangular lattice shape or in a square lattice shape, for example. The plurality of column portions 30 can express the photonic crystal effect.

Note that the “pitch of column portions” is the distance between the centers of column portions 30 adjacent along the predetermined direction. When the planar shape of the column portion 30 is a circle, the “center of the column portion” is the center of such a circle; and when the planar shape of the column portion 30 is a shape other than a circle, it is the center of the minimum inclusion circle. For example, when the planar shape of the column portion 30 is a polygon, the center of the column portion 30 is the center of the smallest circle including the polygon; and when the planar shape of the column portion 30 is an ellipse, it is the center of the smallest circle including the ellipse.

The column portions 30 each include the first semiconductor layer 32, the light-emitting layer 34, the second semiconductor layer 36, and a first electrode 40.

The first semiconductor layer 32 is provided on the buffer layer 22. The first semiconductor layer 32 is provided between the substrate 10 and the light-emitting layer 34. The first semiconductor layer 32 is a semiconductor layer of a first conductive type. The first semiconductor layer 32 is, for example, an n-type GaN layer doped with Si.

The light-emitting layer 34 is provided between the first semiconductor layer 32 and the second semiconductor layer 36. The light-emitting layer 34 generates light when injected with current. The light-emitting layer 34 includes, for example, a well layer and a barrier layer. The well layer and the barrier layer are i-type semiconductor layers not intentionally doped with impurities. The well layer is, for example, an InGaN layer. The barrier layer is, for example, a GaN layer. The light-emitting layer 34 has a multiple quantum well (MQW) structure constituted by the well layer and the barrier layer.

Note that the number of the well layer and the barrier layer that constitute the light-emitting layer 34 is not particularly limited. For example, only one well layer may be provided, in which case the light-emitting layer 34 has a single quantum well (SQW) structure.

The second semiconductor layer 36 is provided on the light-emitting layer 34. The second semiconductor layer 36 is provided between the light-emitting layer 34 and the first electrodes 40. The second semiconductor layer 36 is a semiconductor layer of a second conductive type different from the first conductive type. The second semiconductor layer 36 is, for example, a p-type GaN layer doped with Mg. The first semiconductor layer 32 and the second semiconductor layer 36 are clad layers having a function of confining light within the light-emitting layer 34.

Note that although not illustrated, an optical confinement layer (OCL) formed of an i-type InGaN layer and an i-type GaN layer may be provided at least either between the first semiconductor layer 32 and the light-emitting layer 34, or between the light-emitting layer 34 and the second semiconductor layer 36. Furthermore, the second semiconductor layer 36 may include an electron blocking layer (EBL) formed of a p-type AlGaN layer.

In the light-emitting device 100, a PIN diode is constituted by the p-type second semiconductor layer 36, the i-type light-emitting layer 34 not intentionally doped with impurities, and the n-type first semiconductor layer 32. In the light-emitting device 100, applying a forward bias voltage of the PIN diode between the second electrode 42 and the third electrode 44 causes the light-emitting layer 34 to be injected with current, causing a recombination of electrons and holes at the light-emitting layer 34. This recombination generates light. The light generated at the light-emitting layer 34 propagates in in-plane directions, forms a standing wave due to the photonic crystal effect of the plurality of column portions 30, and receives the gain at the light-emitting layer 34 to lase. Then, the light-emitting device 100 emits +1 order diffracted light and −1 order diffracted light as laser light in the stacking direction.

Although not illustrated, a reflection layer may be provided between the substrate 10 and the buffer layer 22, or under or below the substrate 10. The reflection layer is, for example, a distributed Bragg reflector (DBR) layer. The reflection layer can reflect light generated at the light-emitting layer 34, and the light-emitting device 100 can emit light only from the second electrode 42 side.

Note that in the above description, the light-emitting layer 34 of an InGaN system has been described. However, for the light-emitting layer 34, various material systems capable of emitting light upon injection of current can be used in accordance with the wavelength of light to be emitted. For example, semiconductor materials such as an AlGaN system, an AlGaAs system, an InGaAs system, an InGaAsP system, an InP system, a GaP system, an AlGaP system, or the like can be used.

1.2. Electrodes

The first electrodes 40 are provided on the opposite side of the laminate 20 from the substrate 10. In the illustrated example, the first electrodes 40 are provided on the second semiconductor layer 36. The first electrodes 40 are in contact with the second semiconductor layer 36. The first electrodes 40 are provided between the second semiconductor layer 36 and the second electrode 42. The first semiconductor layer 32, the light-emitting layer 34, the second semiconductor layer 36, and the first electrodes 40 constitute a plurality of column portions 30. In the illustrated example, the space between adjacent column portions 30 is void.

The average refractive index in in-plane directions of the portion at which the first electrodes 40 are provided is lower than the average refractive index in in-plane directions of the portion at which the second semiconductor layer 36 is provided. Here, the average refractive index n_{AVE} in in-plane directions of the portion at which the first electrodes 40 are provided is expressed by the following Equation (1):

[Mathematical Equation 1]

n_{AVE}\sqrt{ε₁·ϕ+ε₂(1−ϕ)} (1)

However, in Equation (1), ε₁ is the dielectric constant of the material constituting the first electrodes 40. ε₂ is the dielectric constant of the material of the space between adjacent column portions 30, which is “1” when the space between adjacent column portions 30 is void. p is the filling ratio of the first electrodes 40 in in-plane directions at the portion at which the first electrodes 40 are provided (the ratio between the cross-sectional area S1 of the first electrodes 40 and the cross-sectional area S2 of the void space (S1/(S1+S2)) when the light-emitting device 100 is cut in a plane parallel to in-plane directions). The average refractive index in in-plane directions of the portion at which the second semiconductor layer 36 is provided, and the average refractive index in in-plane directions of the portion at which the second electrode 42 is provided can also be determined in the same manner as in Equation (1).

The refractive index of the first electrodes 40 is, for example, lower than the refractive index of the second semiconductor layer 36. The resistivity of the first electrodes 40 is lower than the resistivity of the second semiconductor layer 36. The first electrodes 40 are transparent electrodes formed of a metal oxide that transmits light generated at the light-emitting layer 34. The material of the first electrodes 40 is, for example, indium tin oxide (ITO) or ZnO. The material of the first electrodes 40 may be indium gallium zinc oxide (IGZO) made from In, Ga, Zn, and O. In the illustrated example, the thickness of the first electrodes 40 is greater than the thickness of the light-emitting layer 34, and is smaller than the thickness of the second semiconductor layer 36.

The second electrode 42 is provided on the opposite side of the first electrodes 40 from the substrate 10. In the illustrated example, the second electrode 42 is provided on the first electrodes 40. The second electrode 42 is coupled to the plurality of column portions 30. The second electrode 42 is provided across the plurality of column portions 30. In the illustrated example, the second electrode 42 is in contact with the plurality of column portions 30. The second electrode 42 has a continuous film shape that is continuous in in-plane directions. The average refractive index in in-plane directions of the portion at which the second electrode 42 is provided is higher than the average refractive index in in-plane directions of the portion at which the first electrodes 40 are provided. The second electrode 42 is a transparent electrode formed of a metal oxide that transmits light generated at the light-emitting layer 34. The material of the second electrode 42 is, for example, the same as that of the first electrodes 40. The first electrodes 40 and the second electrode 42 represent one electrode for injecting current into the light-emitting layer 34.

The third electrode 44 is provided on the buffer layer 22. The buffer layer 22 may be in ohmic contact with the third electrode 44. The third electrode 44 is electrically coupled to the first semiconductor layer 32. In the illustrated example, the third electrode 44 is electrically coupled to the first semiconductor layer 32 via the buffer layer 22. For the third electrode 44, for example, an electrode such as one in which a Cr layer, an Ni layer, and an Au layer are stacked in this order from the buffer layer 22 side is used. The third electrode 44 represents the other electrode for injecting current into the light-emitting layer 34.

1.3. Action and Advantageous Effects

The light-emitting device 100 includes the first electrodes 40 provided on the opposite side of the laminate 20 from the substrate 10, and the second electrode 42 provided on the opposite side of the first electrodes 40 from the substrate 10. The first electrodes 40 constitute a plurality of column portions 30. The second electrode 42 is coupled to the plurality of column portions 30. Therefore, in the light-emitting device 100, the distance between the light-emitting layer 34 and the second electrode 42 can be increased as compared to a case in which the first electrodes 40 are not provided. Therefore, even if light generated at the light-emitting layer 34 leaks to the second electrode 42 side, light absorbed by the second electrode 42 can be reduced. Further, even if light leaks to the second electrode 42 side, since the first electrodes 40 constitute a plurality of column portions 30, the absorption of light at the first electrodes 40 can be reduced as compared to a case in which the first electrode is a continuous film that is continuous in in-plane directions and does not constitute a plurality of column portions.

Further, in the light-emitting device 100, the first electrodes 40 are transparent electrodes formed of a metal oxide that transmits light generated at the light-emitting layer 34. Therefore, in the light-emitting device 100, the resistance of the first electrodes 40 can be reduced as compared to a case in which the first electrode 40 is constituted by the second semiconductor layer.

Thus, in the light-emitting device 100, it is possible to decrease the resistance while reducing light that leaks to the second electrode 42 side and is absorbed by the second electrode 42. Reducing light that leaks to the second electrode 42 side and is absorbed by the second electrode 42 can lower the lasing threshold. Decreasing the resistance can lower the operating voltage of the light-emitting device 100, and decrease the power consumption.

In the light-emitting device 100, as illustrated in FIG. 1, the average refractive index in in-plane directions is lower at the portion at which the first electrodes 40 are provided than at the portion at which the second semiconductor layer 36 is provided. Therefore, in the light-emitting device 100, the light confinement coefficient can be increased as compared to a case in which the average refractive index in in-plane directions of the portion at which the second semiconductor layer is provided is greater than or equal to the average refractive index in in-plane directions of the portion at which the first electrodes are provided.

Note that FIG. 1 includes a graph illustrating the average refractive index in in-plane directions and the light intensity relative to positions in the stacking direction. In the graph of FIG. 1, the dashed lines indicate the average refractive index and the light intensity when the first electrode is a continuous film that is continuous in in-plane directions and does not constitute a plurality of column portions.

In the light-emitting device 100, the first semiconductor layer 32, the second semiconductor layer 36, and the light-emitting layer 34 constitute a plurality of column portions 30. Therefore, in the light-emitting device 100, a high-quality crystalline light-emitting layer 34 can be obtained, and the strain inherent in the light-emitting layer 34 can be reduced as compared to a case in which the first semiconductor layer, the second semiconductor layer, and the light-emitting layer do not constitute a plurality of column portions.

In the light-emitting device 100, the second electrode 42 is a transparent electrode formed of a metal oxide that transmits light generated at the light-emitting layer 34. Therefore, in the light-emitting device 100, light can be emitted through the second electrode 42.

2. Method of Manufacturing Light-Emitting Device

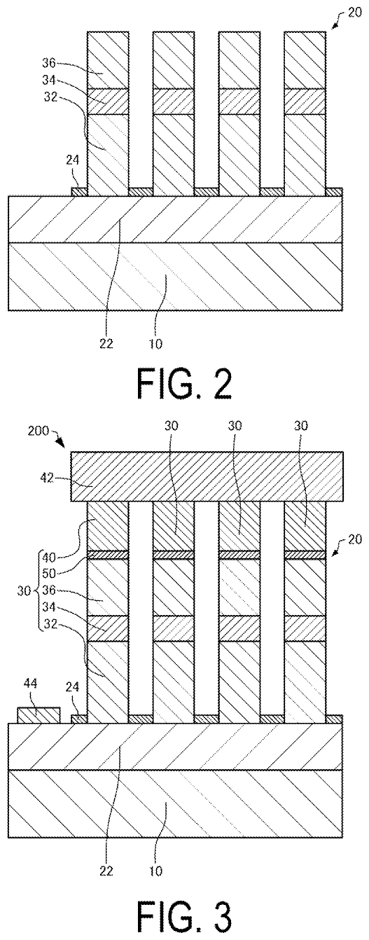

Next, a method of manufacturing the light-emitting device 100 according to the present embodiment will be described with reference to drawings. FIG. 2 is a cross-sectional view schematically illustrating a manufacturing step for the light-emitting device 100 according to the present embodiment.

As illustrated in FIG. 2, the buffer layer 22 is epitaxially grown on the substrate 10. Examples of epitaxial growth methods include metal organic chemical vapor deposition (MOCVD) methods and molecular beam epitaxy (MBE) methods.

Next, a mask layer 24 is formed on the buffer layer 22. The mask layer 24 is formed by, for example, film formation by an electron beam vapor deposition method, a sputtering method, or the like, and patterning. Patterning is performed, for example, by electron beam lithography and dry etching.

Next, with the mask layer 24 serving as the mask, the first semiconductor layer 32, the light-emitting layer 34, and the second semiconductor layer 36 are epitaxially grown in this order on the buffer layer 22. Examples of epitaxial growth methods include MOCVD methods and MBE methods. When an MBE method is used, an RF-MBE method that utilizes a radio-frequency plasma-excited nitrogen source may be used. With this step, the laminate 20 can be formed.

As illustrated in FIG. 1, the first electrodes 40 are formed on the second semiconductor layer 36. The first electrodes 40 are formed by, for example, a sputtering method. Controlling the temperature, pressure, and film formation rate in the sputtering method makes it possible to form first electrodes 40 that maintain their independent columnar shape. With this step, the plurality of column portions 30 can be formed.

Next, the second electrode 42 is formed on the first electrodes 40. The second electrode 42 is formed, for example, by an electron beam vapor deposition method. Forming the second electrode 42 by an electron beam vapor deposition method makes it possible to form a second electrode 42 coupled to the plurality of column portions 30.

Note that the second electrode 42 may be formed by a sputtering method. When the second electrode 42 is formed by a sputtering method, the conditions of the sputtering method are, unlike the conditions of the sputtering method in the step of forming the first electrodes 40, such conditions as cause the second electrode 42 to be coupled to the plurality of column portions 30.

Next, the third electrode 44 is formed on the buffer layer 22. The third electrode 44 is formed by, for example, a sputtering method or a vacuum vapor deposition method. Note that the order of the step of forming the first electrodes 40 and the step of forming the third electrode 44 is not particularly limited. The order of the step of forming the second electrode 42 and the step of forming the third electrode 44 is not particularly limited either.

With the above steps, the light-emitting device 100 can be manufactured.

3. Modified Examples of Light-Emitting Device

### 3.1. First Modified Example

Next, a light-emitting device 200 according to a first modified example of the present embodiment will be described with reference to drawings. FIG. 3 is a cross-sectional view schematically illustrating the light-emitting device 200 according to the first modified example of the present embodiment.

Hereinafter, in the light-emitting device 200 according to the first modified example of the present embodiment, members having a function similar to that of the corresponding components of the light-emitting device 100 according to the present embodiment described above are denoted by the identical reference signs, with detailed description thereof being omitted. The same applies to second to fifth modified examples of the present embodiment to be described below.

As illustrated in FIG. 3, the light-emitting device 200 differs from the light-emitting device 100 described above in that a first metal layer 50 is included.

The first metal layer 50 is provided between the second semiconductor layer 36 and the first electrodes 40. In the illustrated example, the first metal layer 50 constitutes the plurality of column portions 30. The first metal layer 50 transmits light generated at the light-emitting layer 34. The thickness of the first metal layer 50 is not greater than several tens of nm, for example. When the thickness of the first metal layer 50 is not greater than several tens of nm, the first metal layer 50 can transmit light generated at the light-emitting layer 34. The second semiconductor layer 36 may be in ohmic contact with the first metal layer 50.

The resistivity of the first metal layer 50 is lower than the resistivity of the first electrodes 40 and the resistivity of the second electrode 42. For the first metal layer 50, for example, a metal layer such as one in which a Ti layer and an Au layer are stacked in this order from the second semiconductor layer 36 side is used. Providing a Ti layer in contact with the second semiconductor layer 36 can improve the adhesion between the second semiconductor layer 36 and the first metal layer 50 as compared to a case in which no Ti layer is provided. The first metal layer 50 is formed by, for example, an electron beam vapor deposition method or the like.

The light-emitting device 200 includes the first metal layer 50 that is provided between the second semiconductor layer 36 and the first electrodes 40 and that transmits light generated at the light-emitting layer 34. The resistivity of the first metal layer 50 is lower than the resistivity of the first electrodes 40. Therefore, in the light-emitting device 200, the contact resistance between the first metal layer 50 and the second semiconductor layer 36 can be lowered as compared to a case in which the resistivity of the first metal layer is greater than or equal to the resistivity of the first electrodes. This makes it possible to obtain light emission having high uniformity in in-plane directions.

### 3.2. Second Modified Example

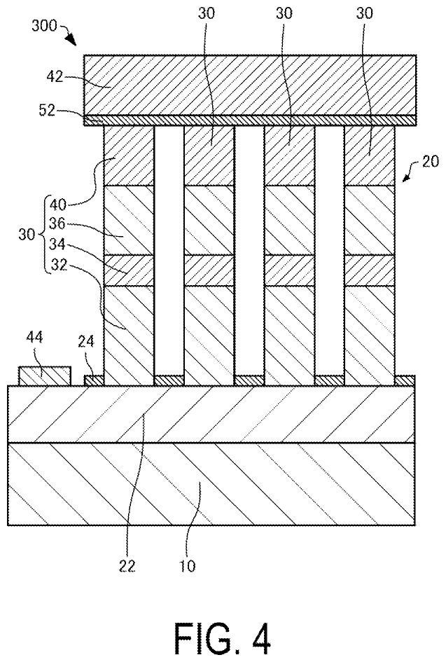

Next, a light-emitting device 300 according to a second modified example of the present embodiment will be described with reference to drawings. FIG. 4 is a cross-sectional view schematically illustrating the light-emitting device 300 according to the second modified example of the present embodiment.

As illustrated in FIG. 4, the light-emitting device 300 differs from the light-emitting device 100 described above in that a second metal layer 52 is included.

The second metal layer 52 is provided between the first electrodes 40 and the second electrode 42. The second electrode 42 is coupled to the plurality of column portions 30 via the second metal layer 52. The second metal layer 52 transmits light generated at the light-emitting layer 34. The thickness of the second metal layer 52 is not greater than several tens of nm, for example. When the thickness of the second metal layer 52 is not greater than several tens of nm, the second metal layer 52 can transmit light generated at the light-emitting layer 34.

The resistivity of the second metal layer 52 is lower than the resistivity of the first electrodes 40 and the resistivity of the second electrode 42. For the second metal layer 52, for example, a metal layer such as one in which a Ti layer and an Au layer are stacked in this order from the first electrodes 40 side is used. Providing a Ti layer in contact with the first electrodes 40 can improve the adhesion between the first electrodes 40 and the second metal layer 52 as compared to a case in which no Ti layer is provided. The second metal layer 52 is formed by, for example, an electron beam vapor deposition method or the like.

The light-emitting device 300 includes the second metal layer 52 that is provided between the first electrodes 40 and the second electrode 42 and that transmits light generated at the light-emitting layer 34. The resistivity of the second metal layer 52 is lower than the resistivity of the second electrode 42. Therefore, in the light-emitting device 300, the contact resistance between the first electrodes 40 and the second metal layer 52 can be lowered as compared to a case in which the resistivity of the second metal layer is greater than or equal to the resistivity of the second electrode. This makes it possible to obtain light emission having high uniformity in in-plane directions.

### 3.3. Third Modified Example

Next, a light-emitting device according to a third modified example of the present embodiment will be described.

In the light-emitting device 100 according to the present embodiment described above, the second electrode 42 is a transparent electrode formed of a metal oxide that transmits light generated at the light-emitting layer 34.

In contrast, in the light-emitting device according to the third modified example of the present embodiment (hereinafter also simply referred to as the “light-emitting device according to the third modified example”), the second electrode 42 is a metal electrode formed of metal. The resistivity of the second electrode 42 is lower than the resistivity of the first electrodes 40. For the second electrode 42, for example, an electrode such as one in which a Ti layer and an Au layer are stacked in this order from the first electrodes 40 side is used. Providing a Ti layer in contact with the first electrodes 40 can improve the adhesion between the first electrodes 40 and the second electrode 42 as compared to a case in which no Ti layer is provided.

The second electrode 42 does not transmit light generated at the light-emitting layer 34. The light-emitting device according to the third modified example is, for example, a flip-chip type light-emitting device that causes light generated at the light-emitting layer 34 to be emitted from the substrate 10 side. In the light-emitting device according to the third modified example, no reflection layer is provided between the substrate 10 and the buffer layer 22, or under or below the substrate 10.

In the light-emitting device according to the third modified example, the resistivity of the second electrode 42 is lower than the resistivity of the first electrodes 40. Therefore, in the light-emitting device according to the third modified example, the resistance of the second electrode 42 can be lowered as compared to a case in which the resistivity of the second electrode is greater than or equal to the resistivity of the first electrodes. This makes it possible to obtain light emission having high uniformity in in-plane directions.

### 3.4. Fourth Modified Example

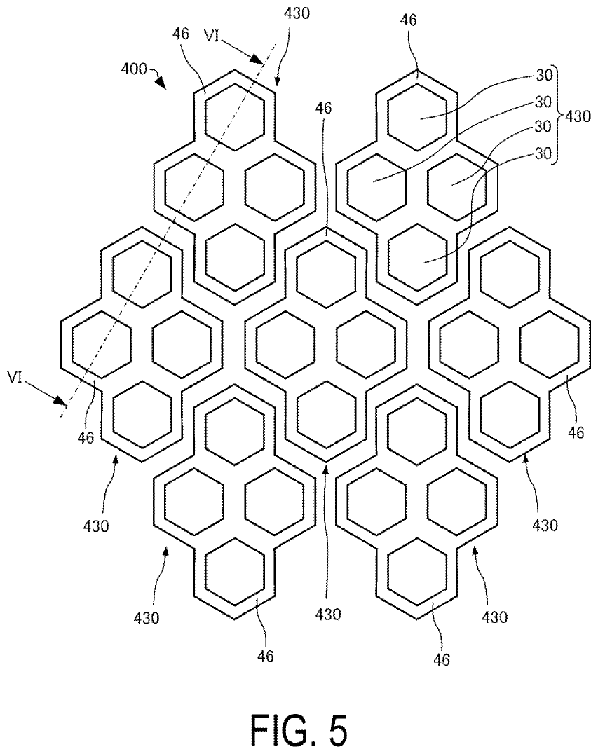

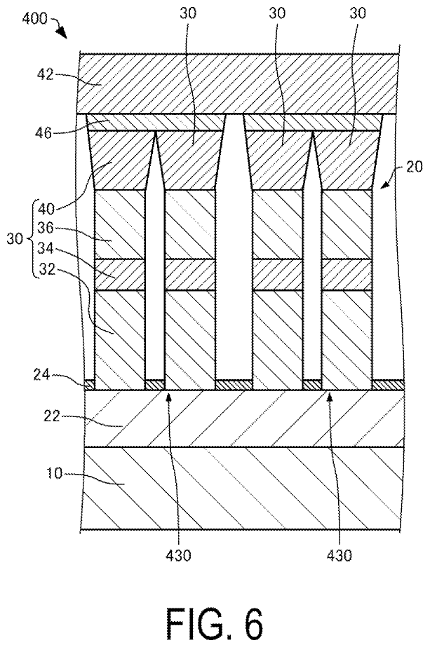

Next, a light-emitting device 400 according to a fourth modified example of the present embodiment will be described with reference to drawings. FIG. 5 is a plan view schematically illustrating the light-emitting device 400 according to the fourth modified example of the present embodiment. FIG. 6 is a cross-sectional view taken along the line VI-VI in FIG. 5 that schematically illustrates the light-emitting device 400 according to the fourth modified example of the present embodiment. Note that in FIG. 5, members other than column portion aggregates 430 and spacer electrodes 46 of the light-emitting device 400 are omitted from illustration for convenience.

As illustrated in FIGS. 5 and 6, the light-emitting device 400 differs from the light-emitting device 100 described above in that the plurality of column portions 30 constitute column portion aggregates 430.

Column portion aggregates 430 are provided in plurality. As illustrated in FIG. 5, the column portion aggregates 430 are arranged in a predetermined pitch in a predetermined direction as viewed from the stacking direction. In the illustrated example, the plurality of column portions 30 are disposed in a triangular lattice shape. One column portion aggregate 430 includes, for example, four column portions 30.

In the light-emitting device 400, forming column portion aggregates 430 with a plurality of column portions 30 can increase the pitch of the periodic structure for expressing the photonic crystal effect even when the diameter of the column portion 30 is small.

As illustrated in FIG. 6, the light-emitting device 400 includes the spacer electrodes 46 provided between the first electrodes 40 and the second electrode 42. In the light-emitting device 400, the first electrodes 40 are formed under conditions that cause the width of the first electrodes 40 to be gradually increased, and the spacer electrodes 46 are each formed across a plurality of column portions 30 constituting one column portion aggregate 430. One spacer electrode 46 is provided for one column portion aggregate 430. The spacer electrodes 46 are each in contact with a plurality of column portions 30. The spacer electrodes 46 are electrodes formed under the same conditions as those of the first electrodes 40. The material of the spacer electrodes 46 is the same as that of the first electrodes 40. The second electrode 42 is provided across the plurality of spacer electrodes 46. The second electrode 42 is coupled to the plurality of column portions 30 via the spacer electrodes 46. The second electrode 42 is an electrode common to the plurality of column portion aggregates 430.

### 3.5. Fifth Modified Example

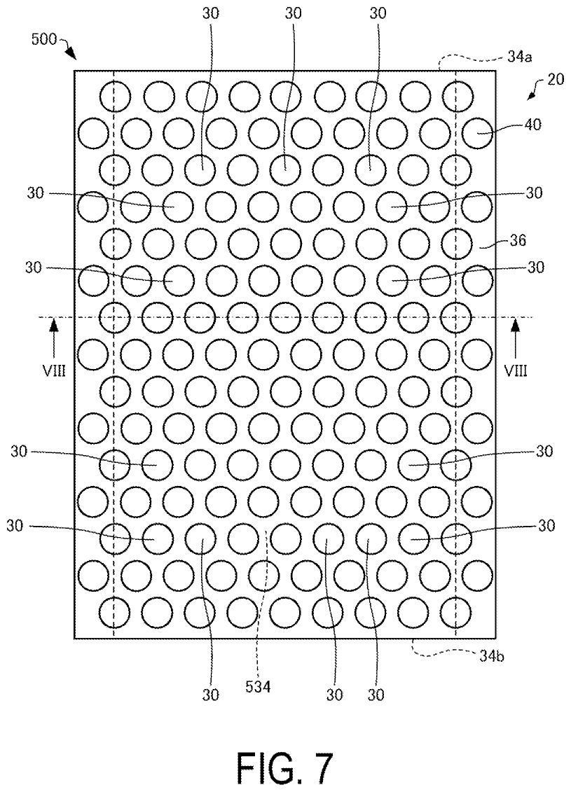

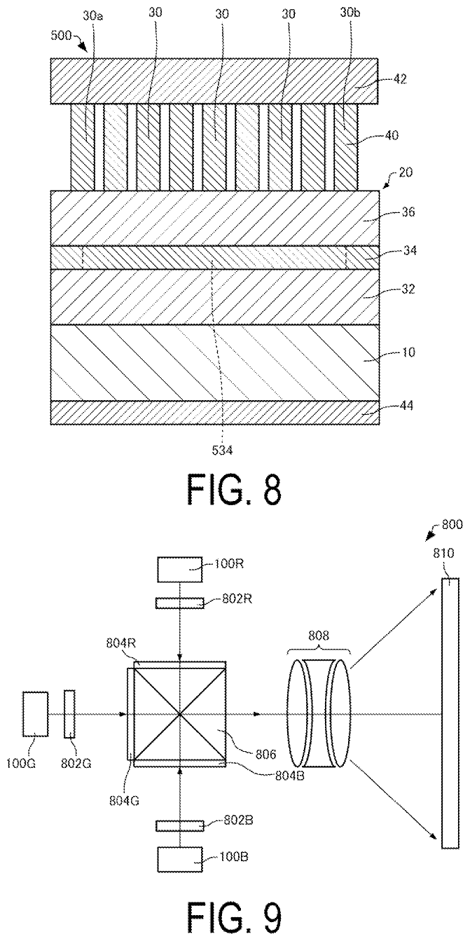

Next, a light-emitting device 500 according to a fifth modified example of the present embodiment will be described with reference to drawings. FIG. 7 is a plan view schematically illustrating the light-emitting device 500 according to the fifth modified example of the present embodiment. FIG. 8 is a cross-sectional view taken along the line VIII-VIII in FIG. 7 that schematically illustrates the light-emitting device 500 according to the fifth modified example of the present embodiment. Note that in FIG. 7, the second electrode 42 is omitted from illustration for convenience.

In the light-emitting device 100 described above, as illustrated in FIG. 1, the first semiconductor layer 32, the light-emitting layer 34, the second semiconductor layer 36, and the first electrodes 40 constitute a plurality of column portions 30.

In contrast, in the light-emitting device 500, as illustrated in FIGS. 7 and 8, the first semiconductor layer 32, the light-emitting layer 34, and the second semiconductor layer 36 do not constitute a plurality of column portions 30. The plurality of column portions 30 are constituted by the first electrodes 40. The first semiconductor layer 32, the light-emitting layer 34, and the second semiconductor layer 36 have a film shape of which the size in in-plane directions is greater than the size in the thickness direction.

As illustrated in FIG. 7, the light-emitting layer 34 has a first side surface 34a and a second side surface 34b. The first side surface 34a and the second side surface 34b are oriented in opposite directions. In the illustrated example, the first side surface 34a and the second side surface 34b are parallel to each other. The plurality of column portions 30 are disposed in a triangular lattice shape, for example. The planar shape of the column portion 30 is, for example, a circle.

A portion of the light-emitting layer 34 constitutes an optical waveguide 534. The optical waveguide 534 can cause light to be guided. First electrodes 40 overlap the optical waveguide 534 as viewed from the stacking direction. Current is injected from the first electrodes 40 into the optical waveguide 534. In the example illustrated in FIG. 8, the plurality of column portions 30 constitute a row. First column portions 30a are located at one end of the row constituted by the plurality of column portions 30, and second column portions 30b are located at the other end thereof. In the illustrated example, as viewed from the stacking direction, the center of the first column portions 30a and one end of the optical waveguide 534 overlap each other, and the center of the second column portions 30b and the other end of the optical waveguide 534 overlap each other.

The third electrode 44 is provided under or below the substrate 10. The substrate 10 has conductivity. The substrate 10 may be in ohmic contact with the third electrode 44. For the third electrode 44, for example, an electrode such as one in which a Cr layer, an Ni layer, and an Au layer are stacked in this order from the substrate 10 side is used.

In the light-emitting device 500, applying a forward bias voltage of the PIN diode between the second electrode 42 and the third electrode 44 creates the optical waveguide 534 at the light-emitting layer 34, causing a recombination of electrons and holes at the light-emitting layer 34 at the optical waveguide 534. This recombination generates light. With this generated light serving as the starting point, stimulated emission continuously takes place, causing the light intensity to be amplified at the optical waveguide 534. While reciprocating in the optical waveguide 534 between the first side surface 34a and the second side surface 34b, light receives the gain to lase, and is emitted from at least one of the first side surface 34a and the second side surface 34b as laser light.

The pitch of the plurality of column portions 30 is smaller than the wavelength of the light generated at the light-emitting layer 34. Therefore, it is possible to inhibit the light traveling in the optical waveguide 534 from being scattered by the plurality of column portions 30.

Note that although not illustrated, an antireflection film may be provided at the first side surface 34a, and a reflection film may be provided at the second side surface 34b. This allows light to be emitted only from the first side surface 34a.

Furthermore, in the example described above, for the optical waveguide 534, an optical waveguide of a gain-guided type of which the shape is defined by current injection from the first electrodes 40 has been described. However, although not illustrated, the optical waveguide 534 may be an optical waveguide of a refractive index-guided type of which the shape is defined by a ridge provided at the second semiconductor layer 36.

Furthermore, the plurality of column portions 30 may be periodically arranged, but need not be periodically arranged. The plurality of column portions 30 may be arranged so as to express the photonic crystal effect.

4. Projector

Next, a projector according to the present embodiment will be described with reference to drawings. FIG. 9 is a view schematically illustrating a projector 800 according to the present embodiment.

The projector 800 includes, for example, light-emitting devices 100 as light source.

The projector 800 includes a housing (not illustrated), and a red light source 100R, a green light source 100G, and a blue light source 100B that are included in the housing and that emit red light, green light, and blue light, respectively. Note that in FIG. 9, the red light source 100R, the green light source 100G, and the blue light source 100B are simplified for convenience.

The projector 800 further includes a first optical element 802R, a second optical element 802G, a third optical element 802B, a first optical modulation device 804R, a second optical modulation device 804G, a third optical modulation device 804B, and a projection device 808, which are included in the housing. The first optical modulation device 804R, the second optical modulation device 804G, and the third optical modulation device 804B are each, for example, a transmission-type liquid crystal light valve. The projection device 808 is, for example, a projection lens.

Light emitted from the red light source 100R is incident on the first optical element 802R. Light emitted from the red light source 100R is focused by the first optical element 802R. Note that the first optical element 802R may have a function other than that of focusing. The same applies to the second optical element 802G and the third optical element 802B to be described later.

Light focused by first optical element 802R is incident on the first optical modulation device 804R. The first optical modulation device 804R modulates incident light in accordance with image information. Then, the projection device 808 enlarges and projects the image formed by the first optical modulation device 804R onto a screen 810.

The light emitted from the green light source 100G is incident on the second optical element 802G. The light emitted from the green light source 100G is focused by the second optical element 802G.

The light focused by the second optical element 802G is incident on the second optical modulation device 804G. The second optical modulation device 804G modulates incident light in accordance with image information. Then, the projection device 808 enlarges and projects the image formed by the second optical modulation device 804G onto the screen 810.

Light emitted from the blue light source 100B is incident on the third optical element 802B. Light emitted from the blue light source 100B is focused by the third optical element 802B.

Light focused by the third optical element 802B is incident on the third optical modulation device 804B. The third optical modulation device 804B modulates incident light in accordance with image information. Then, the projection device 808 enlarges and projects the image formed by the third optical modulation device 804B onto the screen 810.

The projector 800 can also include a cross dichroic prism 806 that synthesizes and guides light emitted from the first optical modulation device 804R, the second optical modulation device 804G, and the third optical modulation device 804B to the projection device 808.

Light of three colors modulated by the first optical modulation device 804R, the second optical modulation device 804G, and the third optical modulation device 804B, respectively, is incident on the cross dichroic prism 806. The cross dichroic prism 806 is formed by bonding together four right-angle prisms. A dielectric multilayer film that reflects red light and a dielectric multilayer film that reflects blue light are disposed on an inner surface of the cross dichroic prism 806, respectively. The light of three colors is synthesized by these dielectric multilayer films to form light representing a color image. Then, the synthesized light is projected onto the screen 810 by the projection device 808, causing an enlarged image to be displayed.

Note that by controlling light-emitting devices 100 as image pixels in accordance with image information, the red light source 100R, the green light source 100G, and the blue light source 100B may directly form an image without using the first optical modulation device 804R, the second optical modulation device 804G, and the third optical modulation device 804B. Then, the projection device 808 may enlarge and project the image formed by the red light source 100R, the green light source 100G, and the blue light source 100B onto the screen 810.

Furthermore, in the example described above, transmission-type liquid crystal light valves are used as optical modulation devices; however, light valves other than liquid crystal light valves may be used, and reflective light valves may be used. Examples of such light valves include reflective liquid crystal light valves and digital micromirror devices. Furthermore, the configuration of the projection device is modified as appropriate depending on the type of light valves used.

The light source can also be applied to a light source device of a scanning type image display device, such as one including a scanning means that is an image forming device and that causes light from a light source to scan a screen and thereby causes an image of a desired size to be displayed on a display surface.

The light-emitting device according to the embodiments described above can be used in applications other than projectors. Applications other than projectors include indoor and outdoor lighting, displays, laser printers, scanners, on-vehicle lights, sensing apparatuses that use light, light sources for communication apparatuses, and display devices for head-mounted displays. Furthermore, the light-emitting device according to the embodiments described above can also be applied to light-emitting elements of LED displays in which minute light-emitting elements are arranged in an array to display an image.

The embodiments and modified examples described above are examples, and the present disclosure is not limited thereto. For example, any of the embodiments and the modified examples can be combined as appropriate.

The present disclosure encompasses configurations that are substantially identical to the configurations described in the embodiments: for example, configurations that have a function, method, and result identical to those of the configurations described in the embodiments, or configurations that have an object and advantageous effect identical to those of the configurations described in the embodiments. The present disclosure also encompasses configurations obtained by replacing a non-essential portion of the configurations described in the embodiments. The present disclosure also encompasses configurations that achieve an action and advantageous effect identical to those of the configurations described in the embodiments, or configurations that can achieve an object identical to that of the configurations described in the embodiments. The present disclosure also encompasses configurations obtained by adding a known technology to the configurations described in the embodiments.

The following contents are derived from the embodiments and modified examples described above.

An aspect of a light-emitting device includes: a substrate; a laminate provided at the substrate; a first electrode provided on an opposite side of the laminate from the substrate; and a second electrode provided on an opposite side of the first electrode from the substrate; wherein the laminate includes a first semiconductor layer of a first conductivity type, a second semiconductor layer of a second conductivity type different from the first conductivity type, and a light-emitting layer provided between the first semiconductor layer and the second semiconductor layer, the first semiconductor layer is provided between the substrate and the light-emitting layer, the first electrode constitutes a plurality of column portions, the second electrode is coupled to the plurality of column portions, and the first electrode is a transparent electrode formed of a metal oxide transmitting light generated at the light-emitting layer.

According to this light-emitting device, it is possible to decrease the resistance while reducing light that leaks to the second electrode side and is absorbed by the second electrode.

In one aspect of the light-emitting device, an average refractive index in a direction orthogonal to a stacking direction of the laminate may be lower at a portion at which the first electrode is provided than at a portion at which the second semiconductor layer is provided.

According to this light-emitting device, the light confinement coefficient can be increased.

In one aspect of the light-emitting device, the first semiconductor layer, the second semiconductor layer, and the light-emitting layer may constitute the plurality of column portions.

According to this light-emitting device, a high-quality crystalline light-emitting layer can be obtained, and the strain inherent in the light-emitting layer can be reduced.

One aspect of the light-emitting device includes: a first metal layer that is provided between the second semiconductor layer and the first electrode and that transmits the light generated at the light-emitting layer; wherein the resistivity of the first metal layer may be lower than the resistivity of the first electrode.

According to this light-emitting device, the contact resistance between the first metal layer and the second semiconductor layer can be lowered.

One aspect of the light-emitting device includes: a second metal layer that is provided between the first electrode and the second electrode and that transmits the light generated at the light-emitting layer; wherein the resistivity of the second metal layer may be lower than the resistivity of the second electrode.

According to this light-emitting device, the contact resistance between the first electrode and the second metal layer can be lowered.

In one aspect of the light-emitting device, the second electrode may be a transparent electrode formed of a metal oxide that transmits the light generated at the light-emitting layer.

According to this light-emitting device, light can be emitted through the second electrode.

In one aspect of the light-emitting device, the resistivity of the second electrode may be lower than the resistivity of the first electrode.

According to this light-emitting device, the resistance of the second electrode can be lowered.

One aspect of a projector includes one aspect of the light-emitting device.

What is claimed is:

1. A light-emitting device comprising:
a substrate;
a laminate provided at the substrate;
a first electrode provided on an opposite side of the laminate from the substrate; and
a second electrode provided on an opposite side of the first electrode from the substrate, wherein
the laminate includes:
a first semiconductor layer of a first conductivity type;
a second semiconductor layer of a second conductivity type different from the first conductivity type; and
a light-emitting layer provided between the first semiconductor layer and the second semiconductor layer,
the first semiconductor layer is provided between the substrate and the light-emitting layer,
the first electrode is included in a plurality of column portions,
the second electrode is coupled to the plurality of column portions, and
the first electrode is a transparent electrode formed of a metal oxide that transmits light generated at the light-emitting layer.

2. The light-emitting device according to claim 1, wherein an average refractive index in a direction orthogonal to a stacking direction of the laminate is lower at a portion provided with the first electrode than at a portion provided with the second semiconductor layer.

3. The light-emitting device according to claim 1, wherein the first semiconductor layer, the second semiconductor layer, and the light-emitting layer are included in the plurality of column portions.

4. The light-emitting device according to claim 1, comprising
a first metal layer that is provided between the second semiconductor layer and the first electrode and that transmits the light generated at the light-emitting layer, wherein
a resistivity of the first metal layer is lower than a resistivity of the first electrode.

5. The light-emitting device according to claim 1, comprising
a second metal layer that is provided between the first electrode and the second electrode and that transmits the light generated at the light-emitting layer, wherein
a resistivity of the second metal layer is lower than a resistivity of the second electrode.

6. The light-emitting device according to claim 1, wherein the second electrode is a transparent electrode formed of a metal oxide that transmits the light generated at the light-emitting layer.

7. The light-emitting device according to claim 1, wherein a resistivity of the second electrode is lower than a resistivity of the first electrode.

8. A projector comprising the light-emitting device according to claim 1.
